(19) United States
(12) Patent Application Publication
(10) Pub. No.: US 2011/0053320 A1
(43) Pub. Date: Mar. 3, 2011

(54) METHOD OF FABRICATING A SEMICONDUCTOR DEVICE

(75) Inventors: Masayuki Miura, Tokyo (JP); Soichi Homma, Kanagawa-ken (JP); Masaya Shima, Kanagawa-ken (JP)

(73) Assignee: KABUSHIKI KAISHA TOSHIBA, Tokyo (JP)

(21) Appl. No.: 12/850,797

(22) Filed: Aug. 5, 2010

(30) Foreign Application Priority Data
Sep. 3, 2009 (JP) 2009-204082

(51) Int. Cl. H01L 21/56

(52) U.S. Cl. 438/126; 257/E21.502

(57) ABSTRACT

According to one embodiment, a method of fabricating a semiconductor device is disclosed. The method can include forming a debonding layer constituted with a thermoplastic resin on a supporting material, and forming an insulating layer constituted with a thermosetting resin including a solvent dissolving the thermoplastic resin on the debonding layer.

### CROSS REFERENCE TO RELATED APPLICATION

This application is based upon and claims the benefit of priority from prior Japanese Patent Application No. 2009-204082, filed on Sep. 3, 2009, the entire contents of which are incorporated herein by reference.

### FIELD

Exemplary embodiment described herein relates to a method of fabricating a semiconductor device.

### BACKGROUND

Recently, semiconductor device having a ball grid array (BGA) have been increased with accompanying increasing pins in the semiconductor device. In BGA process, semiconductor chip is encapsulated in an interposer in which a wiring layer and an insulating layer are layered.

Further, the semiconductor chip is connected to an outer terminal via the wiring layer of the interposer.

The interposer is formed on a debonding layer formed on a supporting material, for example, a silicon substrate, as a method of fabricating a semiconductor device using the interposer.

For one fabricating method, the semiconductor chip is mounted on the interposer to be encapsulated by resin, subsequently, the interposer is separated from the supporting material.

When the method mentioned above is performed, the debonding layer is formed by using a thermoplastic resin and the insulating layer constituted with the thermosetting resin is formed as the lowest layer in the interposer, for example.

In this case, adhesiveness between the debonding layer and the insulating layer is week, and thermal expansion coefficients of the debonding layer and the insulating layer are different each other. Accordingly, the interface between the debonding layer and the insulating layer may be peeled by thermal stress in heating of the processing steps forming the interposer.

When the debonding at the interface is generated, the interposer is not fixed on the supporting material. As a result, problems are generated in the processing steps. Forming a wiring layer being demanded to precise process accuracy cannot be performed, for example.

### BRIEF DESCRIPTION OF THE DRAWINGS

FIG. 1 is a schematic cross-sectional view showing a method of fabricating a semiconductor device according to an embodiment;

FIG. 2 is a schematic cross-sectional view showing an interposer formed by using the method of fabricating the semiconductor device according to the embodiment;

FIG. 3 is a schematic cross-sectional view showing a semiconductor device being mounted the interposer formed by using the method of fabricating the semiconductor device according to the embodiment;

FIG. 4 is an explanatory view showing debonding a debonding layer in the method of fabricating the semiconductor device according to the embodiment;

FIG. 5 is an explanatory view showing the semiconductor device after debonding the debonding layer in the method of fabricating the semiconductor device according to the embodiment;

FIG. 6 is an explanatory view showing removing a mixing layer in the method of fabricating the semiconductor device according to the embodiment;

FIG. 7 is an explanatory view showing the semiconductor device after removing the mixing layer in the method of fabricating the semiconductor device according to the embodiment;

### DETAILED DESCRIPTION

In general, according to one embodiment, a method of fabricating a semiconductor device is disclosed. The method can include forming a debonding layer constituted with a thermoplastic resin on a supporting material, and forming an insulating layer constituted with a thermosetting resin including a solvent dissolving the thermoplastic resin on the debonding layer.

An embodiment will be described below in detail with reference to the attached drawings mentioned above. It should be noted that the present invention is not restricted to the embodiments but covers their equivalents. Throughout the attached drawings, similar or same reference numerals show similar, equivalent or same components.

### Embodiment

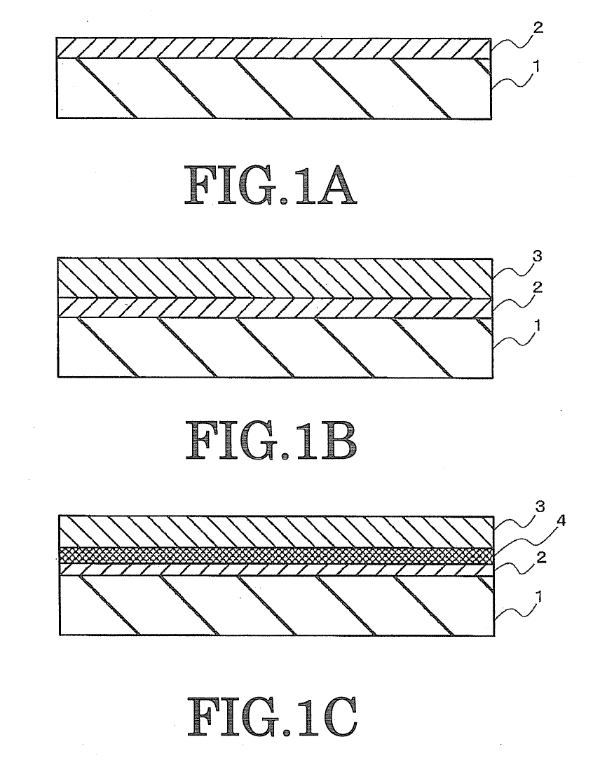

First, a method of a semiconductor device according to an embodiment will be described below in detail with, reference to FIG. 1. FIG. 1 is a schematic cross-sectional view showing the semiconductor device.

As shown in FIG. 1A, a supporting material 1 is prepared. A debonding layer 2 constituted with a thermoplastic resin is formed on the supporting material 1.

The supporting material 1 has material properties which can resist to a heat treatment, a chemical treatment or the like in fabricating desirable semiconductor device. The supporting material 1 is a silicon substrate, a glass substrate, a metal substrate constituted with SUS or the like, for example.

Polystyrene, metacrylate resin series, polyethylene, polypropylene series, cellulosic resin or the like is used as the thermoplastic resin of the debonding layer 2. Further, the viscosity may be favorable below 1×10⁵ cps in heating up to a temperature of 250° C.

As mentioned above, the thermoplastic resin is coated on the supporting material 1 by using spin coating, printing, laminating or the like, and is hardened, so that the debonding layer 2 is formed.

As shown in FIG. 1B, a thermosetting resin is coated, for example, by spin coating, on the debonding layer 2 to form an insulating layer 3.

The thermosetting resin as the insulating layer 3 includes a solvent dissolving the thermoplastic resin used as the debonding layer 2. Ethyl lactate or the like is used as the solvent.

The thermoplastic resin as the debonding layer 2 is dissolved at near interface with the insulating layer 3 by the solvent.

In such a manner as shown in FIG. 1C, a mixing layer 4 constituted with the thermoplastic resin and the thermosetting resin is formed between the debonding layer 2 and the insulating layer 3. The thermoplastic resin and the thermosetting resin are the materials of the debonding layer 2 and the insulating layer 3, respectively.

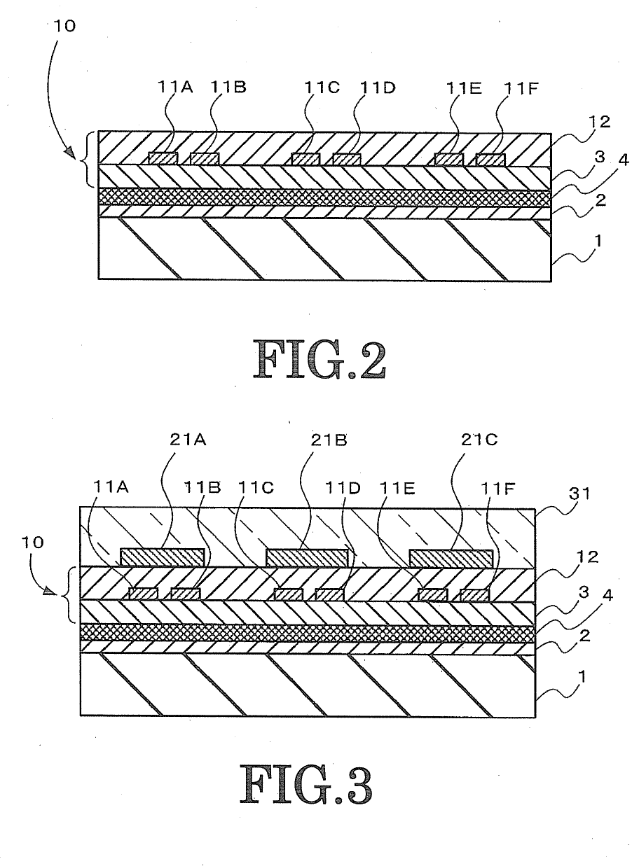

FIG. 2 shows an example of an interposer 10 with the insulating layer 3 as the lowest layer.

Here, wiring layers 11 (11A-11F) are formed on the insulating layer 3, and an insulating layer 12 is formed on the wiring layer 11 as the interposer 10, for an example.

Forming the mixing layer 4 between the debonding layer 2 and the insulating layer 3 improves adhesiveness between the debonding layer 2 and the insulating layer 3. As a result, debonding at the interface between the debonding layer 2 and the insulating layer 3 is not generated in the heat treatment of forming the interposer 10, so that the position of the interposer 10 on the supporting material 1 is stably retained. Consequently, accuracy in the wiring pattern of the wiring layer 11, for example, or the like is improved. Therefore, processing accuracy and fabricating'yield of the interposer 10 can be improved.

FIG. 3 shows an example which is a semiconductor device having a plurality of semiconductor chips mounted in the interposer 10.

Here, semiconductor chips 21A-21C are disposed in the interposer 10 and encapsulated by the encapsulating resin layer 31 are illustrated as an example.

In mounting such semiconductor chips, debonding at the interface between the debonding layer 2 and the insulating layer 3 is not generated by heating. Accordingly, the position of the interposer 10 on the supporting material 1 is stably retained. As a result, position accuracy and assembly yield of the semiconductor chips 21A-21C disposed in the interposer 10 can be improved.

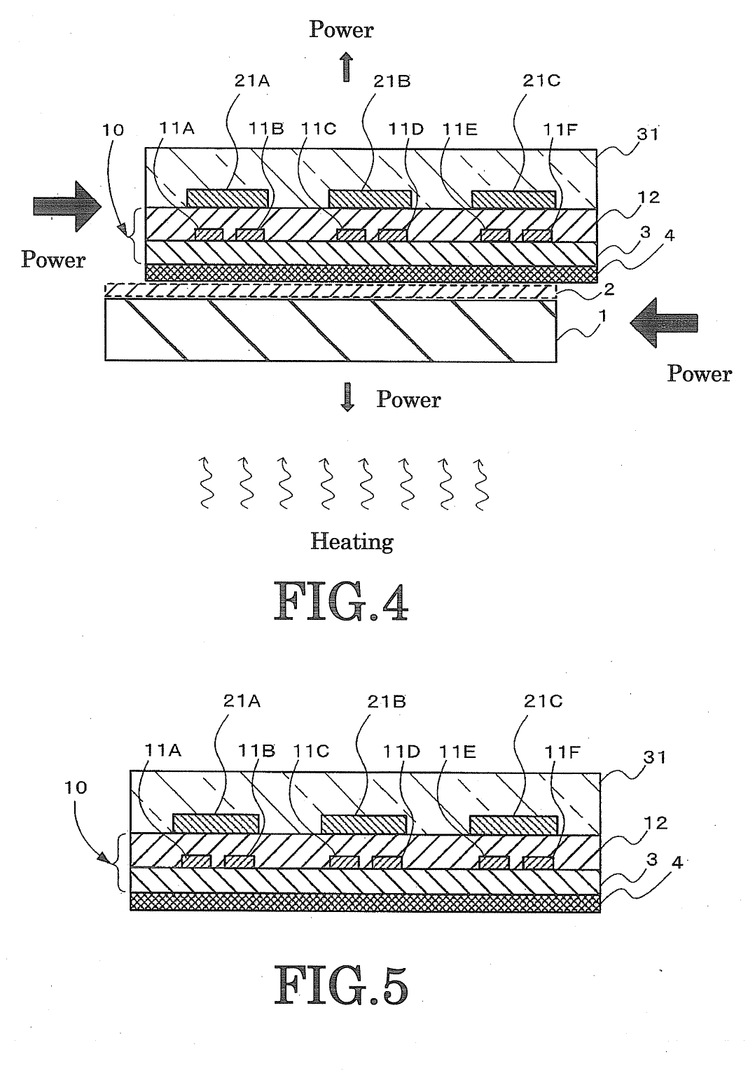

As shown in FIG. 4, the semiconductor device encapsulated by the resin is heated at a temperature of 200-250° C., so that viscosity of the thermoplastic resin forming the debonding layer 2 is lowered. Simultaneously, stress is applied to inverse directions each other between the supporting material 1 and the stacked layer which is constituted from the insulating layer 3 including the mixing layer 4 to the encapsulating resin layer 31, so that the stacked layer mentioned above and the supporting material 1 is relatively shifted to a parallel direction. In such a way, a shear stress against the debonding layer 2 is generated to shear the debonding layer 2, so that the stacked layer is separated from the supporting material 1. Furthermore, in addition to nearly parallel movement mentioned above, the stacked layer is pull to a perpendicular direction some extent to be moved, so that the separation mentioned above can be proceeded.

In the process, the heating temperature is set to be 200-250° C. Accordingly, the semiconductor device encapsulated by the resin is not thermally damaged such as degradation of the wiring layer 11 of the interposer 10. Further, as mentioned above, viscosity of the thermoplastic resin constituting the debonding layer 2 is below 1×10⁵ cps at a temperature of 250° C.

FIG. 5 shows an example of a semiconductor device which is separated from the supporting material 1. As shown in FIG. 5, a portion of the mixing layer 4 and a portion of the debonding layer 2 are remained at the bottom of the semiconductor device, to connect to an outer terminal for covering the electrode.

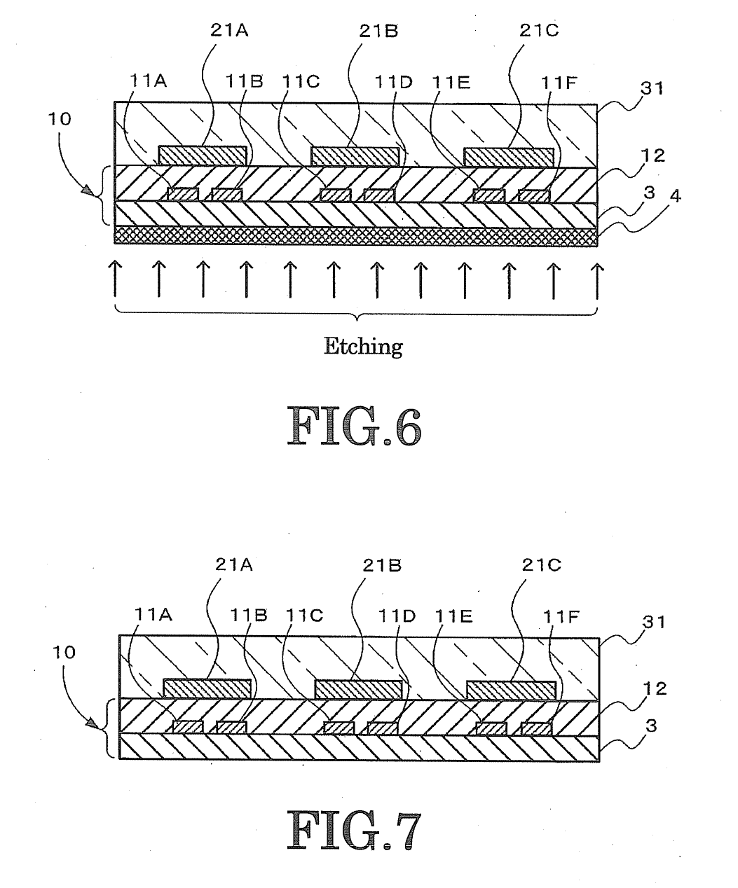

As shown in FIG. 6, a bottom of the semiconductor device is etched by oxygen-treating or the like to remove portions of the mixing layer 4 and the debonding layer 2, so that the insulating layer 3 and the electrodes are exposed.

FIG. 7 shows an example of the semiconductor device in which the mixing layer 4 is shifted.

According to the embodiment, the semiconductor device mentioned below can be obtained. When the insulating layer 3 is formed by using the thermosetting resin, the thermosetting resin is coated on the debonding layer 2 including the solvent dissolving the thermoplastic resin used as forming the debonding layer 2. The solvent included in the thermosetting resin dissolves the thermoplastic resin near the interface at the insulating layer 3. Consequently, the mixing layer 4 constituted with the thermoplastic resin and the thermosetting resin is formed between the debonding layer 2 and the insulating layer 3. The thermoplastic resin and the thermosetting resin are the materials of the debonding layer 2 and the insulating layer 3, respectively.

Forming the mixing layer 4 prevents debonding at the interface between the debonding layer 2 and the insulating layer 3 in heating, when the interposer 10 is formed or the semiconductor chip is mounted on the interposer 10 including encapsulation.

As debonding at the interface between the debonding layer 2 and the insulating layer 3 is not generated, the position of the interposer 10 on the supporting material 1 can be stably retained. As a result, processing accuracy of the interposer 10 can be improved, and the position of the semiconductor chip disposed on the interposer 10 can be precisely improved.

The generation of debonding at the interface between the debonding layer and the insulating layer as the lowest layer in the interposer can be prevented in fabricating the interposer and encapsulating the semiconductor chip including assembly according to the present embodiment.

While certain embodiments have been described, these embodiments have been presented by way of example only, and are not intended to limit the scope of the inventions. Indeed, the novel methods and equipments described herein may be embodied in a variety of other forms; furthermore, various omissions, substitutions and changes in the form of the methods and equipments described herein may be made without departing from the spirit of the inventions. The accompanying claims and their equivalent are intended to cover such forms or modifications as would fall within the scope and sprit of the inventions.

What is claimed is:

1. A method of fabricating a semiconductor device, comprising:
forming a debonding layer constituted with a thermoplastic resin on a supporting material; and
forming an insulating layer constituted with a thermosetting resin including a solvent dissolving the thermoplastic resin on the debonding layer.

2. The method of claim 1, wherein
the thermoplastic resin is dissolved with the solvent, so that a mixing layer constituted with components of the debonding layer and the insulating layer is formed between the debonding layer and the insulating layer.

3. The method of claim 2, further comprising:
forming an interposer which has the insulating layer as the lowest layer.

4. The method of claim 2, further comprising:
relatively shifting the insulating layer including the mixing layer to the supporting material in heating the debonding layer to shear the debonding layer and to separate the insulating layer including the mixing layer from the supporting material.

5. The method of claim 4, further comprising:
removing the mixing layer.

6. The method of claim 5, further comprising:
mounting a semiconductor chip on the interposer.

7. The method of claim 6, further comprising:
encapsulating a resin on the semiconductor chip.

8. The method of claim 1, wherein
a material of the supporting material is constituted with at least one of a semiconductor, a glass and a metal.

9. The method of claim 1, wherein
a material of the debonding layer is constituted with at least one of polystyrene series, metacrylate resin series, polyethylene series, polypropylene series and cellulose resin series.

10. The method of claim 1, wherein
viscosity of the debonding layer is below 1×10⁵ cps at a temperature of 250° C.

11. The method of claim 1, wherein
the debonding layer is coated by spin coating, printing or laminating.

12. The method of claim 4, wherein
the debonding layer is heated in a range of 200-250° C.

13. The method of claim 1, wherein
the solvent is ethyl lactate.
